(19) United States
(12) Patent Application Publication
(10) Pub. No.: US 2022/0189397 A1
(43) Pub. Date: Jun. 16, 2022

(54) PIXEL CIRCUIT AND DISPLAY PANEL

(71) Applicant: WUHAN CHINA STAR OPTOELECTRONICS TECHNOLOGY CO., LTD., Wuhan, Hubei (CN)

(72) Inventors: Haiming CAO, Wuhan, Hubei (CN); Chao TIAN, Wuhan, Hubei (CN)

(21) Appl. No.: 17/057,664

(22) PCT Filed: Sep. 16, 2020
(86) PCT No.: PCT/CN2020/115622

§ 371 Date: Nov. 22, 2020

(30) Foreign Application Priority Data
Aug. 31, 2020 (CN) 202010900163.0

(51) Int. Cl. G09G 3/3233; H01L 27/32

(52) U.S. Cl. CPC G09G 3/3233; H01L 27/3265

(57) ABSTRACT

A pixel circuit and a display panel related to the field of display technology are provided. The pixel circuit and the display panel include a driving transistor, a first transistor, a second transistor, a first capacitor, and a second capacitor. The pixel circuit and the display panel, before emitting light, preset an electric potential of a gate, a drain, and a source of a driving transistor. As a result, a light-emitting current passing the driving transistor can be immune from a threshold voltage of the driving transistor during luminescence, further eliminating an ununiform luminescence phenomenon due to a drift of the threshold voltage.

### FIELD OF INVENTION

The present application relates to the field of display technology, especially to the field of driving circuit technology, and specifically to a pixel circuit and a display panel.

### BACKGROUND OF INVENTION

With development of display technology, requirements of display quality have become increasingly higher. While high-frequency dynamic picture display (smoother picture quality) is in urgent demand, low power ordinary display is also required, and therefore dynamic frame frequency technology has emerged, which can simultaneously satisfy requirements of display panels for ultra-low frequency (1 Hz to 5 Hz) and ultra-high frequency (120 Hz to 360 Hz). Meanwhile, requirements for display areas is also increased, that is, a strong charging capacity for a short charging time in each row under a high-frequency condition, and a strong picture holding capacity for extending holding time of each frame under a low-frequency condition.

Low temperature polycrystalline oxide (LTPO) combines advantages of two technologies of low temperature poly-silicon (LTPS) and indium gallium zinc oxide (IGZO). Pixel circuits adopting thin film transistors of such LTPO type show features of strong driving capacity and low power consumption, and have become a popular technology in the display field.

However, driving transistors in a conventional pixel circuit are restricted by factors of their manufacturing process, circuit design, etc., and threshold voltages of the driving transistors drift frequently, which leads to ununiform luminescence in a display area, affecting performance of LTPO type thing film transistors when they are applied to dynamic frame frequency technology.

### SUMMARY OF INVENTION

The present application provides a pixel circuit and a display panel, and resolves a problem of ununiform luminescence due to drifting of threshold voltages of driving transistors.

As a first aspect, the present application provides a pixel circuit that includes a driving transistor, a first transistor, a second transistor, a first capacitor, and a second capacitor. The driving transistor is in series with a light-emitting loop consisting of a first power signal and a second power signal, and is configured to control current flowing through the light-emitting loop. The first transistor is in series between a drain of the driving transistor and a gate of the driving transistor, and is configured to control a transmitting path formed between the drain and the gate of the driving transistor according to a first scan signal. The second transistor is connected to the gate of the driving transistor and one of a source or a drain of the first transistor, and is configured to write a data signal and an input reference signal according to a second scan signal to reset an electric potential of the gate of the driving transistor and an electric potential of a source thereof and compensate the electric potential of the source of the driving transistor through the transmitting path. The first capacitor is in series between the gate of the driving transistor and the source thereof, and is configured to store the electric potential of the gate of the driving transistor. The second capacitor is in series between the source of the driving transistor and the first power signal, and is configured to regulate the electric potential of the gate of the driving transistor.

Based on the first aspect, in a first embodiment of the first aspect, a channel type of the driving transistor is different from a channel type of the first transistor and a channel type of the second transistor, and a channel material of the driving transistor is different from a channel material of the first transistor and a channel material of the second transistor.

Based the first embodiment of the first aspect, in a second embodiment of the first aspect, the channel type of the first transistor is the same as the channel type of the second transistor, and the channel material of the first transistor is the same as the channel material of the second transistor.

Based the second embodiment of the first aspect, in a third embodiment of the first aspect, the pixel circuit further includes a first light-emitting control transistor, wherein one of a source or a drain of the first light-emitting control transistor is connected to the first power signal, the other of the source or the drain of the first light-emitting control transistor is connected to the source of the driving transistor, and a gate of the first light-emitting control transistor is connected to a first light-emitting control signal.

Based the third embodiment of the first aspect, in a fourth embodiment of the first aspect, the pixel circuit further includes a second light-emitting control transistor, wherein one of a source or a drain of the second light-emitting control transistor is connected to the drain of the driving transistor, and a gate of the second light-emitting control transistor is connected to a second light-emitting control signal.

Based the fourth embodiment of the first aspect, in a fifth embodiment of the first aspect, the pixel circuit further includes at least one light-emitting device, wherein the other of the source or the drain of the second light-emitting control transistor is connected to an anode of the light-emitting device, and a cathode of the light-emitting device is connected to the second power signal.

Based the fifth embodiment of the first aspect, in a sixth embodiment of the first aspect, the channel type of the driving transistor is the same as a channel type of the first light-emitting control transistor and a channel type of the second light-emitting control transistor, and the channel material of the driving transistor is the same as a channel material of the first light-emitting control transistor and a channel material of the second light-emitting control transistor.

Based the sixth embodiment of the first aspect, in a seventh embodiment of the first aspect, the driving transistor is a p-channel poly-silicon thin film transistor, and the first transistor and the second transistor are an n-channel polycrystalline oxide thin film transistor.

Based any one of the above-described embodiments of the first aspect, in an eighth embodiment of the first aspect, an electric potential of the first power signal is higher than an electric potential of the second power signal, and the first power signal and the second power signal are both a constant voltage signal.

As a second aspect, the present application provides a display panel that includes at least one of the pixel circuits according to any one of the above-described embodiments.

The pixel circuit and the display panel according to the present application, before emitting light, preset an electric potential of a gate, a drain, and a source of a driving transistor. As a result, a light-emitting current passing the driving transistor can be immune from a threshold voltage of the driving transistor during luminescence, further eliminating an ununiform luminescence phenomenon due to a drift of the threshold voltage.

### DESCRIPTION OF DRAWINGS

FIG. 1 is a circuit principle diagram of a pixel circuit according to an embodiment of the present application.

FIG. 2 is a signal flow schematic diagram of the pixel circuit in FIG. 1 operating in a reset phase.

FIG. 3 is a signal flow schematic diagram of the pixel circuit in FIG. 1 operating in a compensating phase.

FIG. 4 is a signal flow schematic diagram of the pixel circuit in FIG. 1 operating in a writing phase.

FIG. 5 is a signal flow schematic diagram of the pixel circuit in FIG. 1 operating in a light-emitting phase.

FIG. 6 is a timing diagram of the pixel circuit in FIG. 1.

FIG. 7 is another timing diagram of the pixel circuit in FIG. 1.

### DETAILED DESCRIPTION OF PREFERRED EMBODIMENTS

For better clearness and definiteness of purpose, technical approach, and effect of the present application, the following further describes embodiments of the present application in detail with reference to accompanying drawings. It should be understood that the embodiments described here is merely for explaining the present application and not intended to limit the present application.

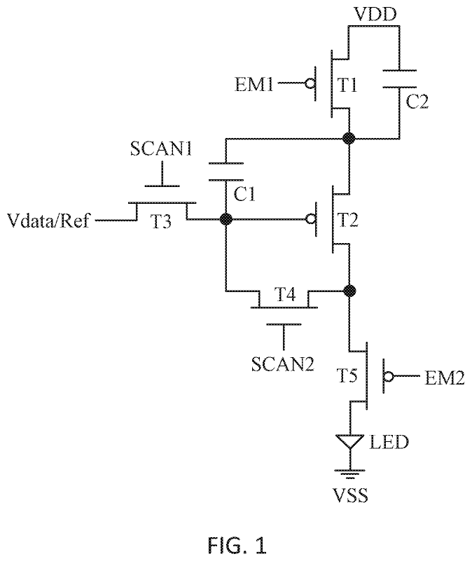

As shown in FIG. 1 to FIG. 7, the present embodiment provides a pixel circuit that includes a driving transistor T2, a first transistor T4, a second transistor T3, a first capacitor C1, and a second capacitor C2. The driving transistor T2 is in series with a light-emitting loop consisting of a first power signal VDD and a second power signal VSS, and is configured to control current flowing through the light-emitting loop. The first transistor T4 is in series between a drain of the driving transistor T2 and a gate of the driving transistor T2, and is configured to control a transmitting path formed between the drain and the gate of the driving transistor T2 according to a first scan signal SCAN2. The second transistor T3 is connected to the gate of the driving transistor T2 and one of a source or a drain of the first transistor T4, and is configured to write a data signal Vdata and an input reference signal Ref according to a second scan signal SCAN1 to reset an electric potential of the gate of the driving transistor T2 and an electric potential of a source thereof and compensate the electric potential of the source of the driving transistor T2 through the transmitting path. The first capacitor C1 is in series between the gate of the driving transistor T2 and the source thereof, and is configured to store the electric potential of the gate of the driving transistor T2. The second capacitor C2 is in series between the source of the driving transistor T2 and the first power signal VDD, and is configured to regulate the electric potential of the gate of the driving transistor T2. The drain of the driving transistor T2 is connected to the other of the source or the drain of the first transistor T4.

As shown in FIG. 1, in one embodiment, the pixel circuit further includes a first light-emitting control transistor T1, a second light-emitting control transistor T5, and at least one light-emitting device LED.

Specifically, one of a source or a drain of the first light-emitting control transistor T1 is connected to the first power signal VDD, the other of the source or the drain of the first light-emitting control transistor T1 is connected to the source of the driving transistor T2, and a gate of the first light-emitting control transistor T1 is connected to a first light-emitting control signal EM1. One of a source or a drain of the second light-emitting control transistor T5 is connected to the drain of the driving transistor T2, a gate of the second light-emitting control transistor T5 is connected to a second light-emitting control signal EM2, and the other of the source or the drain of the second light-emitting control transistor T5 is connected to an anode of the light-emitting device LED. A cathode of the light-emitting device LED is connected to the second power signal VSS.

It should be explained that an electric potential of the first power signal VDD is higher than that of the second power signal VSS, and the first power signal VDD and the second power signal VSS are both a constant voltage signal.

The light-emitting device LED can be but is not limited to an organic light-emitting diode (OLED), it can also be self-luminescent devices including a micro LED, a mini LED, etc.

In one embodiment, a channel type of the driving transistor T2 is different from that of the first transistor T4 and of the second transistor T3, and a channel material of the driving transistor T2 is different from that of the first transistor T4 and of the second transistor T3. The channel type of the first transistor T4 is the same as that of the second transistor T3, and the channel material of the first transistor T4 is the same as that of the second transistor T3. In one embodiment, the channel type of the driving transistor T2 is the same as that of the first light-emitting control transistor T1 and of the second light-emitting control transistor T5, and the channel material of the driving transistor T2 is the same as that of the first light-emitting control transistor T1 and of the second light-emitting control transistor T5.

Specifically, the driving transistor T2, the first light-emitting control transistor T1, and the second light-emitting control transistor T5 can be but is not limited to a p-channel poly-silicon thin film transistor, they can also be a p-channel low temperature poly-silicon (LTPS) thin film transistor. The first transistor T4 and the second transistor T3 can be but is not limited to an n-channel polycrystalline oxide thin film transistor, they can also be an n-channel low temperature polycrystalline oxide (LTPO) thin film transistor or an n-channel low temperature polycrystalline metal oxide thin film transistor.

The description above of the pixel circuit according to the present disclosure tells that the pixel circuit adopts five thin film transistors at most, and in comparison with pixel circuits having more thin film transistors, during a manufacturing process, the pixel circuit according to the present disclosure can effectively increase yields.

Operation of the pixel circuit according to the present disclosure is divided into following phases:

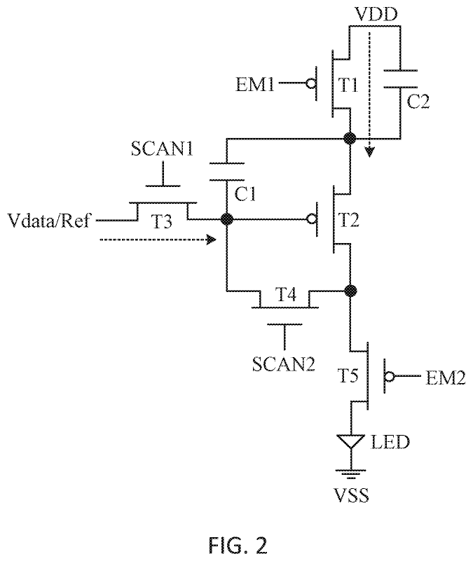

A reset phase Rst: the first light-emitting control signal EM1 is at a low electric potential, the second light-emitting control signal EM2 is at a high electric potential, the first scan signal SCAN2 is at a low electric potential, and the second scan signal SCAN1 is at a high electric potential. At this time, the second transistor T3 is turned on, and the reference signal Ref resets the electric potential of the gate of the driving transistor T2. Meanwhile, the first light-emitting control transistor T1 is turned on, and the first power signal VDD resets the electric potential of the source of the driving transistor T2. Arrows shown in FIG. 2 indicate directions of signal flow of the pixel circuit in the reset phase Rst.

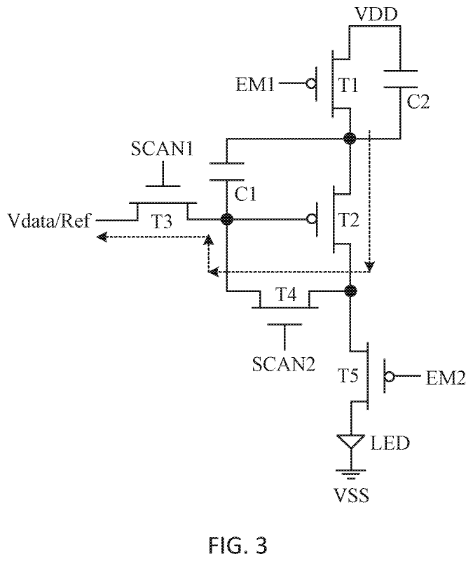

A compensating phase Pgm: the first light-emitting control signal EM1 is at a high electric potential, the second light-emitting control signal EM2 is at a high electric potential, the first scan signal SCAN2 is at a high electric potential, and the second scan signal SCAN1 is at a high electric potential. At this time, the first light-emitting control transistor T1 and the second light-emitting control transistor T5 are both turned off, the first transistor T4 and the second transistor T3 are both turned on, and the electric potential of the source of the driving transistor T2 discharges sequentially through its drain, the first transistor T4, and the second transistor T3, until an electric potential difference between the gate and the source of the driving transistor T2 equals a threshold voltage of the driving transistor T2. Arrows shown in FIG. 3 indicate directions of signal flow of the pixel circuit in the compensating phase Pgm.

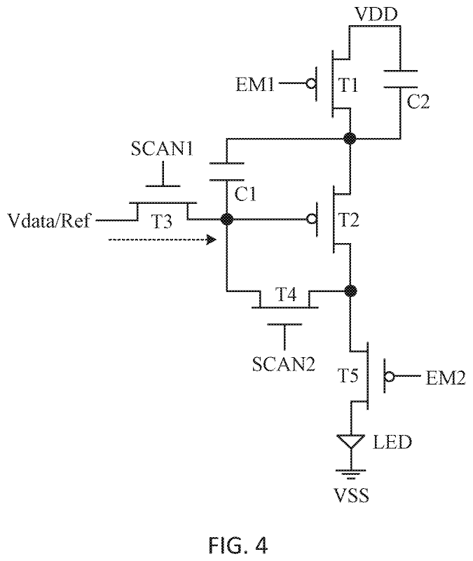

A writing phase WR: the first light-emitting control signal EM1 is at a high electric potential, the second light-emitting control signal EM2 is at a high electric potential, the first scan signal SCAN2 is at a low electric potential, and the second scan signal SCAN1 is at a high electric potential. At this time, the second transistor T3 is turned on, the data signal Vdata is written into the gate of the driving transistor T2. Arrows shown in FIG. 4 indicate directions of signal flow of the pixel circuit in the writing phase WR.

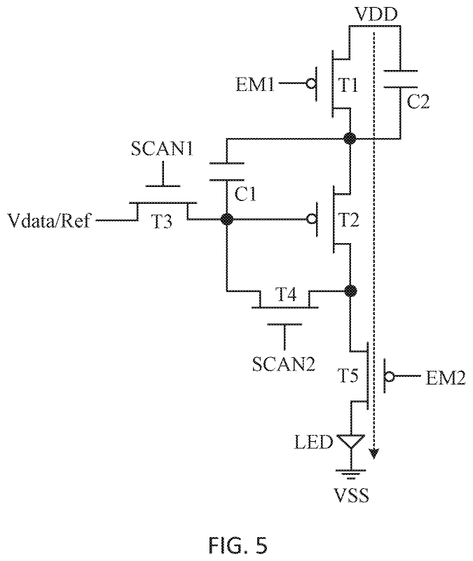

A light-emitting phase EM: the first light-emitting control signal EM1 is at a low electric potential, the second light-emitting control signal EM2 is at a low electric potential, the first scan signal SCAN2 is at a low electric potential, and the second scan signal SCAN1 is at a low electric potential. At this time, the first light-emitting control transistor T1, the second light-emitting control transistor T5, and the driving transistor T2 are all turned on, the light-emitting loop conducts, and the driving transistor T2 controls current flowing through the light-emitting loop conducts to drive the light-emitting device LED illuminate with a corresponding brightness. Arrows shown in FIG. 5 indicate directions of signal flow of the pixel circuit in the light-emitting phase EM.

The following table shows voltages of main nodes of the driving transistor T2 in each of the above-described operation phases:

| phase/ | | | | |
|---|---|---|---|---|
| node | | | | |
| electric | | | | |
| potential | G | S | D | Vgs |
| Rst | Vref | Vdd | Vled | Vref − Vdd |
| Pgm | Vref | Vref − Vth | Vref | Vth |
| WR | Vdata | Vref − Vth + (Vdata − Vref) * K | Vref | (Vdata − Vref) * (1 − K) + Vth |
| EM | Vdata + | Vref − Vth + (Vdata − Vref) * K + | Vled | (Vdata − Vref + V1) * (1 − K) + Vth |
| | V1 * K | V1 | | |

Wherein, G, S, D, and Vgs are the electric potential of the gate of the driving transistor T2, the electric potential of its source, the electric potential of its drain, and the electric potential difference between the gate and the source, respectively. Vref is an electric potential of the reference signal Ref, Vth is the threshold voltage of the driving transistor T2, Vdd is an electric potential of the first power signal VDD, V1 is an electric potential of the second power signal VSS, Vdata is an electric potential of the data signal, and Vled is an electric potential of the anode of the light-emitting device LED. K=C1/(C1+C2), wherein C1 is capacitance of the first capacitor, and C2 is capacitance of the second capacitor. Therefore, magnitude of light-emitting current I of the light-emitting phase is:

I=(m·u·W)/2L*((Vdata−Vref+V1)*(1−K))²

Wherein, m, u, W, and L in the above formula are constants and their description is omitted here. It can be seen from this formula that the magnitude of the light-emitting current I no longer relates to the threshold voltage of the driving transistor T2. Therefore, the pixel circuit according to the present application can be immune from the threshold voltage of the driving transistor T2, facilitating ununiform luminescence in a display area.

During the above-described operations, the gate of the driving transistor T2 constantly blocks the source of the driving transistor T2, and through simultaneously setting the gate and the drain of the driving transistor T2 to a bottom level, a level of the source is discharged to Vgs=Vth to finish compensation. Furthermore, through cooperation of the first capacitor C1 and the second capacitor C2, the data signal Vdata can be written into the gate and the source of the driving transistor T2, realizing regulation of an electric potential difference Vgs between the gate and the source of the driving transistor T2, and further realizing a current source function under a Vth compensation state. On this basis, when replacing the first transistor T4 and the second transistor T3 that are connected to the gate of the driving transistor T2 with low temperature polycrystalline oxide thin film transistors having lower leakage current, a maintenance time of a level of the gate of the driving transistor T2 can be further extended, even more facilitating realization of ultra-low frequency and low power consumption display, while providing better visual experience.

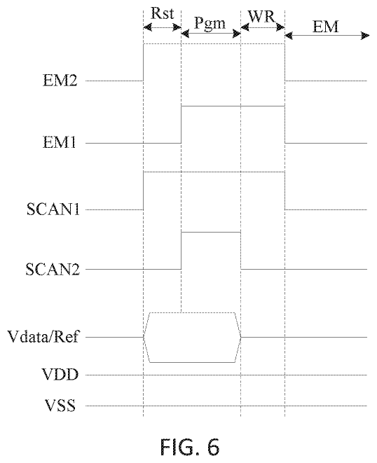

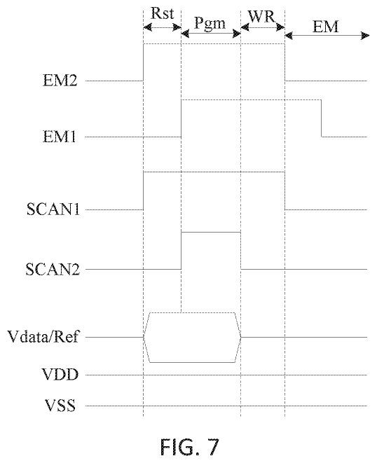

In one embodiment of the pixel circuit according to the present disclosure, the second scan signal SCAN 1 and the second light-emitting control signal EM2 can also use a same control signal, which can be the second scan signal SCAN 1 or the second light-emitting control signal EM2. In this way, an input signal line can be saved for the pixel circuit. Furthermore, as shown in FIG. 6, when a pulse width of the first light-emitting control signal EM1 is different from that of the second light-emitting control signal EM2, it requires two different light-emitting driving circuits (EM GOA) to provide corresponding light-emitting control signals. As shown in FIG. 7, when a pulse width of the first light-emitting control signal EM1 is identical to that of the second light-emitting control signal EM2, the first light-emitting control signal EM1 and the second light-emitting control signal EM2 can use a same light-emitting driving circuit. For example, the second light-emitting control signal EM2 of a next row and a scan signal of the next row can be adopted as the first light-emitting control signal EM1. In this way, a light-emitting driving circuit can be saved to effectively reduce border space. Furthermore, at least one input signal line or two input signal lines can be decreased to further optimize layout of signal lines in a display area.

In one embodiment, the present application provides a display panel that includes at least one of the pixel circuits according to any one of the above-described embodiments.

The display panel can include a plurality of pixel circuits, the plurality of pixel circuits include a plurality of light-emitting devices LED, and the plurality of light-emitting devices LED is arranged on the display panel as an array.

It can be understood that, for a person of ordinary skill in the art, equivalent alteration or changes can be made according to technical approaches and invention thought of the present application, and all the changes or alteration is within the scope protected by appended claims of the present application.

What is claimed is:

1. A pixel circuit, comprising:
a driving transistor in series with a light-emitting loop consisting of a first power signal and a second power signal and configured to control current flowing through the light-emitting loop;
a first transistor in series between a drain of the driving transistor and a gate of the driving transistor and configured to control a transmitting path formed between the drain and the gate of the driving transistor according to a first scan signal;
a second transistor connected to the gate of the driving transistor and one of a source or a drain of the first transistor and configured to write a data signal and an input reference signal according to a second scan signal to reset an electric potential of the gate of the driving transistor and an electric potential of a source of the driving transistor and compensate the electric potential of the source of the driving transistor through the transmitting path;
a first capacitor in series between the gate of the driving transistor and the source of the driving transistor and configured to store the electric potential of the gate of the driving transistor; and
a second capacitor in series between the source of the driving transistor and the first power signal and configured to regulate the electric potential of the gate of the driving transistor.

2. The pixel circuit as claimed in claim 1, wherein a channel type of the driving transistor is different from a channel type of the first transistor and a channel type of the second transistor, and a channel material of the driving transistor is different from a channel material of the first transistor and a channel material of the second transistor.

3. The pixel circuit as claimed in claim 2, wherein the channel type of the first transistor is same as the channel type of the second transistor, and the channel material of the first transistor is same as the channel material of the second transistor.

4. The pixel circuit as claimed in claim 3, further comprising a first light-emitting control transistor, wherein one of a source or a drain of the first light-emitting control transistor is connected to the first power signal, the other of the source or the drain of the first light-emitting control transistor is connected to the source of the driving transistor, and a gate of the first light-emitting control transistor is connected to a first light-emitting control signal.

5. The pixel circuit as claimed in claim 4, further comprising a second light-emitting control transistor, wherein one of a source or a drain of the second light-emitting control transistor is connected to the drain of the driving transistor, and a gate of the second light-emitting control transistor is connected to a second light-emitting control signal.

6. The pixel circuit as claimed in claim 5, further comprising at least one light-emitting device, wherein the other of the source or the drain of the second light-emitting control transistor is connected to an anode of the light-emitting device, and a cathode of the light-emitting device is connected to the second power signal.

7. The pixel circuit as claimed in claim 6, wherein the channel type of the driving transistor is same as a channel type of the first light-emitting control transistor and a channel type of the second light-emitting control transistor, and the channel material of the driving transistor is same as a channel material of the first light-emitting control transistor and a channel material of the second light-emitting control transistor.

8. The pixel circuit as claimed in claim 7, wherein the driving transistor is a p-channel poly-silicon thin film transistor, and the first transistor and the second transistor are an n-channel polycrystalline oxide thin film transistor.

9. The pixel circuit as claimed in claim 1, wherein an electric potential of the first power signal is higher than an electric potential of the second power signal, and the first power signal and the second power signal are both a constant voltage signal.

10. A display panel, comprising at least one of the pixel circuit as claimed in claim 1.

11. The display panel as claimed in claim 10, wherein the first transistor and the second transistor are a low temperature polycrystalline oxide thin film transistor.

12. The display panel as claimed in claim 11, wherein a channel type of the driving transistor is different from a channel type of the first transistor and a channel type of the second transistor, and a channel material of the driving transistor is different from a channel material of the first transistor and a channel material of the second transistor.

13. The display panel as claimed in claim 12, wherein the channel type of the first transistor is same as the channel type of the second transistor.

14. The display panel as claimed in claim 13, wherein the pixel circuit further comprises a first light-emitting control transistor, wherein one of a source or a drain of the first light-emitting control transistor is connected to the first power signal, the other of the source or the drain of the first light-emitting control transistor is connected to the source of the driving transistor, and a gate of the first light-emitting control transistor is connected to a first light-emitting control signal.

15. The display panel as claimed in claim 14, wherein the pixel circuit further comprises a second light-emitting control transistor, wherein one of a source or a drain of the second light-emitting control transistor is connected to the drain of the driving transistor, and a gate of the second light-emitting control transistor is connected to a second light-emitting control signal.

16. The display panel as claimed in claim 15, wherein the pixel circuit further comprises at least one light-emitting device, wherein the other of the source or the drain of the second light-emitting control transistor is connected to an anode of the light-emitting device, and a cathode of the light-emitting device is connected to the second power signal.

17. The display panel as claimed in claim 16, wherein the channel type of the driving transistor is same as a channel type of the first light-emitting control transistor and a channel type of the second light-emitting control transistor, and the channel material of the driving transistor is same as a channel material of the first light-emitting control transistor and a channel material of the second light-emitting control transistor.

18. The display panel as claimed in claim 17, wherein the driving transistor is a p-channel poly-silicon thin film transistor, and the first transistor and the second transistor are an n-channel thin film transistor.

19. The display panel as claimed in claim 10, wherein an electric potential of the first power signal is higher than an electric potential of the second power signal, and the first power signal and the second power signal are both a constant voltage signal.
